(19) United States
(12) Patent Application Publication
(10) Pub. No.: US 2020/0165480 A1
(43) Pub. Date: May 28, 2020

(54) PHOTOCROSSLINKABLE FLUOROPOLYMER COATING COMPOSITION AND COATING LAYER FORMED THEREFROM

(71) Applicant: The Chemours Company FC, LLC, Wilmington, DE (US)

(72) Inventors: XUDONG CHEN, HOCKESSIN, DE (US); ROBERT CLAYTON WHELAND, WILMINGTON, DE (US)

(73) Assignee: THE CHEMOURS COMPANY FC, LLC, Wilmington, DE (US)

(21) Appl. No.: 16/631,699

(22) PCT Filed: Jul. 17, 2018
(86) PCT No.: PCT/US2018/042399

§ 371 Date: Jan. 16, 2020

Related U.S. Application Data
(60) Provisional application No. 62/535,546, filed on Jul. 21, 2017.

(51) Int. Cl. C09D 127/18; C08F 214/26; G03F 7/075; H01L 21/02

(52) U.S. Cl. CPC C09D 127/18; C08F 214/267; G03F 7/162; H01L 21/0212; G03F 7/0757

(57) ABSTRACT

The present disclosure relates to a photocrosslinkable fluoropolymer coating composition, a coating layer comprising a photocrosslinked fluoropolymer and a process for forming the coating layer. Coating layers comprising the crosslinked fluoropolymer have low dielectric constants, low water absorptivity, good adhesion to conventional electronic device substrates, and are able to be photoimaged so as to provide the very fine features needed for modern electronic devices.

### CROSS-REFERENCE TO RELATED APPLICATIONS

This application claims the benefit of U.S. provisional patent application No. 62/535,546, filed Jul. 21, 2017, which is herein incorporated by reference in its entirety.

### FIELD OF THE DISCLOSURE

The present disclosure is directed toward coating layers comprising photocrosslinked fluoropolymer, compositions and processes for forming the coating layer and articles comprising the coating layer. The fluoropolymer is a copolymer produced from the polymerization of a fluoroolefin, an alkyl or aryl vinyl ether and an alkenyl silane.

### BACKGROUND OF DISCLOSURE

Polymers are used in electronic devices to provide structural support and insulation as well as for protecting the device from physical damage and from water. The value of these polymers in these applications is greatly increased if the polymers are photoimageable, i.e., photocrosslinkable, allowing for formation of patterns with defined dimensions, so as to provide a three-dimensional framework for the interconnection of multiple electronic components and layers.

As electronic devices become smaller, move to higher frequencies and have lower power consumptions, conventional materials used in the manufacture of electronic devices such as polyimides are not able to meet the demands for new materials having lower dielectric constant, lower loss tangent, lower moisture absorption, and adhesion to substrates. Such conventional polymers used in this field for electronic device passivation have dielectric constants in the range of from 3.0 to 3.3 for example, and water absorptivities ranging from 0.8 to 1.7 percent for example. Water absorption is a significant drawback of conventional polyimides in electronic device applications, and can result in the formation of acids which cause corrosion of metals and inorganics in the devices. Such corrosion is undesirable as it can result in device failure through erosion of signal transmission quality and delamination of the passivation layer from the surface coated. Further, water absorption of a passivation layer is undesirable from the point of view of dielectric constant, which is very sensitive to and undesirably raised by increased water content of polymers comprising passivation layers. These deficiencies are especially a concern in newer electronic devices wherein data is transmitted at high frequency. The higher the frequency of operation of the device, the more sensitive it is to performance deterioration from absorbed water.

There is a continuing need for polymeric materials for use as coating layers in electronic devices that have lower dielectric constants, lower water absorptivities, better adhesion to substrates and that can be photoimaged in order to produce electronic components and layers.

### SUMMARY OF THE DISCLOSURE

This disclosure relates to a coating layer comprising a layer of photocrosslinked coating composition disposed on at least a portion of a substrate, wherein the coating composition comprises: i) a photocrosslinkable fluoropolymer having repeat units arising from monomers comprising: (a) fluoroolefin selected from the group consisting of tetrafluoroethylene, chlorotrifluoroethylene, hexafluoropropylene, perfluoro(methyl vinyl ether), perfluoro(ethyl vinyl ether), and perfluoro(propyl vinyl ether); (b) alkyl vinyl ether wherein the alkyl group is a C1 to C6 straight chain saturated hydrocarbon radical or a C3 to C6 branched chain or cyclic saturated hydrocarbon radical, or aryl vinyl ether wherein the aryl group is unsubstituted or substituted; and (c) alkenyl silane of the formula SiR1R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical; ii) a photoacid generator; and iii) an optional photosensitizer; wherein the photocrosslinkable fluoropolymer has a number average molecular weight of from 10,000 to 350,000 daltons, and wherein the photocrosslinked coating composition has a dielectric constant of from 2.0 to 3.0 when measured at 1 MHz, and wherein the layer of photocrosslinked coating composition has a thickness of from 0.5 to 15 micrometers and has photocrosslinked features having a width of 0.5 micrometers or greater.

This disclosure also relates to a process for manufacture of the aforementioned coating layer, comprising; (1) providing the aforementioned photocrosslinkable coating composition further containing carrier medium; (2) applying a layer of the photocrosslinkable coating composition further containing carrier medium onto at least a portion of a substrate; (3) removing at least a portion of the carrier medium; (4) irradiating at least a portion of the layer of the photocrosslinkable coating composition with ultraviolet light; (5) heating the applied layer of photocrosslinkable coating composition; and (6) removing at least a portion of the uncrosslinked photocrosslinkable fluoropolymer.

This disclosure also relates to a composition comprising the aforementioned photocrosslinkable coating composition.

The present coating layers solve industry needs in that they have low dielectric constant, low water absorptivity, good adhesion to conventional electronic device substrates, and are able to be photoimaged so as to provide the very fine features needed in modern electronic devices.

### BRIEF DESCRIPTION OF THE DRAWINGS

The drawings described herein are for illustration purposes only. The drawings are not necessarily to scale, with emphasis being placed upon illustrating the principles of the following disclosure. The drawings are not intended to limit the scope of the present disclosure in any way.

FIG. 1 shows a drawing of a cross section of a substrate containing a layer of the coating composition.

FIG. 2 shows a photomicrograph (with 20 micrometer scale bar) of a plan view of a wafer having a patterned coating layer in accordance with one embodiment of the present invention.

FIG. 3 shows a photomicrograph (with added measurement bars) of a plan view of a wafer having a patterned coating layer in accordance with one embodiment of the present invention.

FIG. 4 shows a photomicrograph (with added measurement bars) of a plan view of a wafer having a patterned coating layer in accordance with one embodiment of the present invention.

FIG. 5 shows a photomicrograph (with added measurement bars) of a plan view of a wafer having a patterned coating layer in accordance with one embodiment of the present invention.

FIG. 6 shows a photomicrograph (with added measurement bars) of a plan view of a wafer having a patterned coating layer in accordance with one embodiment of the present invention.

### DETAILED DESCRIPTION

The features and advantages of the present disclosure will be more readily understood by those of ordinary skill in the art from reading the following detailed description. It is to be appreciated that certain features of the disclosure, which are, for clarity, described above and below in the context of separate embodiments, may also be provided in combination in a single element. Conversely, various features of the disclosure that are, for brevity, described in the context of a single embodiment, may also be provided separately or in any sub-combination. In addition, references to the singular may also include the plural (for example, “a” and “an” may refer to one or more) unless the context specifically states otherwise.

The use of numerical values in the various ranges specified in this application, unless expressly indicated otherwise, are stated as approximations as though the minimum and maximum values within the stated ranges were both proceeded by the word “about”. In this manner, slight variations above and below the stated ranges can be used to achieve substantially the same results as values within the ranges. Also, the disclosure of these ranges is intended as a continuous range including each and every value between the minimum and maximum values.

As used herein:

The term “photocrosslinked” means a crosslinked fluoropolymer wherein the crosslinks within the polymer network are formed as a result of the action of light. For example, compositions comprising the photocrosslinkable fluoropolymer also contain one or more of a photoacid generator and an optional photosensitizer. Irradiating the composition with light of the appropriate wavelength generates acid functional molecules that react with the silane groups on the fluoropolymer resulting in the crosslinking of the fluoropolymer.

The phrase “photocrosslinkable fluoropolymer” means an uncrosslinked fluoropolymer that is capable of being photocrosslinked when irradiated with the appropriate wavelength of light in the presence of one or more of a photoacid generator and, optionally, a photosensitizer.

The phrase “photocrosslinked features” refers to the size of the structures that can be produced according to the process of the present disclosure. The photocrosslinked features are defined by the width of the feature formed and by the thickness of the layer of the photocrosslinked coating composition. For example, the disclosed process can form 4 micrometer lines in a coating that is 2 micrometers thick. It should be noted that the photocrosslinked feature refers to the void that is formed when the uncrosslinked fluoropolymer is removed. For example, where a series of lines are formed, the photocrosslinked feature refers to the width of the void produced when the uncrosslinked fluoropolymer material is removed forming the void. The photocrosslinked features can be formed by irradiating a portion of a layer of the coating composition, heating the applied layer of coating composition, then removing the uncrosslinked portions of the coating composition, for example, by dissolving and carrying away in a solvent.

The phrase “passivation layer” means a layer that provides the underlying substrate to which it is attached protection from environmental damage. For example, damage from water, oxidation and chemical degradation. The passivation layer has both barrier properties and forms a dielectric layer on the substrate that can be used to separate two conductor layers or two semiconductor layers or a conductive layer from a semiconductor layer. The passivation layer can also be used as a bank layer in a light emitting diode structure that separates the various wells of light emitting diode material from contacting one another.

The phrase “unreactive solvent” means one or more solvents for the photocrosslinkable fluoropolymer or for the coating composition comprising the photocrosslinkable fluoropolymer wherein the unreactive solvent does not become a part of the final crosslinked network as a result of the photocrosslinking with the photocrosslinkable fluoropolymer.

The present disclosure relates to a coating layer comprising a photocrosslinked coating composition wherein the photocrosslinked coating composition comprises a photocrosslinked fluoropolymer. In one embodiment the coating layer is a passivation layer. The coating layer can be used as a barrier layer and/or an insulating layer in a thin film transistor, organic field effect transistor, semiconductor, semiconductor oxide field effect transistor, integrated circuit, light emitting diode (LED), bank layers for LEDs, including organic LEDs, display device, flexible circuit, solder mask, photovoltaic device, printed circuit board, an interlayer dielectric, optical waveguide, a micro electromechanical system (MEMS), a layer of an electronic display device or a layer of a microfluidic device or chip. The coating layer can also form a layer that is in the form of a patterned surface for electrowetting applications. The crosslinked coating composition can provide very small photocrosslinked features and provides low dielectric constants, low water absorptivity, and good adhesion to electronic device substrates.

The coating layer comprises a layer of photocrosslinked coating composition disposed on at least a portion of a substrate, wherein the coating composition comprises i) a photocrosslinkable fluoropolymer, ii) a photoacid generator, and iii) an optional photosensitizer, wherein the photocrosslinkable fluoropolymer has a number average molecular weight of from 10,000 to 350,000 daltons, and, wherein the layer of photocrosslinked coating composition has a dielectric constant of from 2.0 to 3.0 when measured at 1 MHz, and wherein the layer of the photocrosslinked coating composition has a thickness of from 0.5 to 15 micrometers and has photocrosslinked features having a width of 0.5 micrometers or greater. In other embodiments, the width of the photocrosslinked feature (resolution) is from 1 to 10 micrometers.

An important property for a coating layer in an electronic device is to have a low amount of water absorptivity. The present coating layer has very low water absorptivity. In one embodiment water absorptivity is assessed by subjecting a sample of photocrosslinked coating composition to measurement in a controlled humidity chamber by dynamic vapor sorption (DVS) methodology at standard temperature from 90% to 10% relative humidity. Typical water absorption values of the present photocrosslinked coating composition range from 0.01 to 0.8 percent by weight. In other embodiments, the water absorptivity is from 0.05 to 0.2 percent by weight, and in still further embodiments, is 0.1 percent by weight.

The present photocrosslinkable fluoropolymer includes repeating units arising from fluoroolefin monomer. Fluoroolefin is at least one monomer selected from the group consisting of tetrafluoroethylene, chlorotrifluoroethylene, hexafluoropropylene, perfluoro(methyl vinyl ether), perfluoro(ethyl vinyl ether), and perfluoro(propyl vinyl ether). In some embodiments, in addition to these fluoroolefins, the photocrosslinkable fluoropolymer can contain repeat units arising from other fluorinated monomers capable of copolymerizaing into the present fluoropolymer, including: trifluoroethylene, vinyl fluoride, vinylidene fluoride, perfluorodimethyldioxole, trifluoropropylene, perfluoro(2-methylene-4-methyl-1,3-dioxolane, hexafluoroisobutylene, methyl 3-[1-[difluoro[(trifluorovinyl)oxy]methyl]-1,2,2,2-tetrafluoroethoxy]-2,2,3,3-tetrafluoropropionate, 2-[1-[difluoro[(1,2,2-trifluoroethenyl)oxy]methyl]-1,2,2,2-tetrafluoroethoxy]-1,1,2,2-tetrafluoro-ethanesulfonyl fluoride, or a combination thereof. In some embodiments, the fluoroolefin monomers forming the photocrosslinkable fluoropolymer can consist of, or consist essentially of, the aforementioned fluoroolefins.

Fluoroolefin is incorporated into the photocrosslinkable fluoropolymer in an amount of from 40 to 60 mole percent, based on the total amount of repeating units in the fluoropolymer. In some embodiments, fluoroolefin is incorporated into the fluoropolymer in an amount of from 42 to 58 mole percent. In other embodiments, fluoroolefin is incorporated into the fluoropolymer in an amount of from 45 to 55 mole percent.

The present photocrosslinkable fluoropolymer includes repeating units arising from at least one alkyl vinyl ether monomer and/or aryl vinyl ether monomer. Alkyl vinyl ethers as used herein are those wherein the alkyl group is a C1 to C6 straight chain saturated hydrocarbon radical or a C3 to C6 branched chain or cyclic saturated hydrocarbon radical. Example alkyl vinyl ethers include methyl vinyl ether, ethyl vinyl ether, n-propyl vinyl ether, isopropyl vinyl ether, n-butyl vinyl ether, sec-butyl vinyl ether, t-butyl vinyl ether, n-pentyl vinyl ether, isoamyl vinyl ether, hexyl vinyl ether, and cyclohexyl vinyl ether. In some embodiments, the alkyl vinyl ether consists of or consists essentially of methyl vinyl ether, ethyl vinyl ether, n-propyl vinyl ether, isopropyl vinyl ether or a combination thereof. Aryl vinyl ether as used herein are those wherein the aryl group is unsubstituted (phenyl) or substituted (e.g., alkylphenyl (e.g., tolyl, xylyl, —C₆H₄(CH₂CH₃)), halophenyl, aminophenyl). Example aryl vinyl ethers include phenyl vinyl ether.

Alkyl and/or aryl vinyl ethers are incorporated into the photocrosslinkable fluoropolymer in an amount of from 40 to 60 mole percent, based on the total amount of repeating units in the fluoropolymer. In some embodiments, alkyl and/or aryl vinyl ether is incorporated into the fluoropolymer in an amount of from 42 to 58 mole percent. In other embodiments alkyl and/or aryl vinyl ether is incorporated into the fluoropolymer in an amount of from 45 to 55 mole percent.

The present photocrosslinkable fluoropolymer includes repeating units arising from at least one alkenyl silane monomer. Alkenyl silanes as used herein correspond to the general formula SiR1R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical or substituted or unsubstituted cyclic C5-C6 alkoxy radical.

The alkenyl silane R1 ethylenically unsaturated hydrocarbon radical is an unsaturated hydrocarbon radical capable of productively copolymerizing into the photocrosslinkable fluoropolymer backbone together with fluoroolefin and alkyl or aryl vinyl ether. In some embodiments the ethylenically unsaturated hydrocarbon radicals are those having from 2 to 5 carbon atoms. In some embodiments the ethylenically unsaturated hydrocarbon radical is ethenyl (vinyl), 2-propenyl (allyl), 1-propenyl, 2-butenyl, 1,3-butadienyl, 2-pentenyl, and the like. In a preferred embodiment the ethylenically unsaturated hydrocarbon radical is ethenyl.

The alkenyl silane R2 radical is aryl, aryl substituted hydrocarbon radical, branched C3-C6 alkoxy radical or substituted or unsubstituted cyclic C5-C6 alkoxy radical. The R2 radical was chosen by the present inventor to be a relatively sterically bulky substituent bonded to the silicon atom of the silane. This was discovered by the present inventor to allow for productive copolymerization and incorporation of the alkenyl silane through the ethylenically unsaturated hydrocarbon radical into the photocrosslinkable fluoropolymer backbone chain, and also result in the fluoropolymer having phase stable shelf-life, for example, such that it remains dissolved in organic solvent and does not undesirably form gel at ambient temperatures and without special precautions for at least 3 months (e.g, does not form gel through hydrolysis of the silane alkoxy radicals, followed by silicon-oxygen crosslinking (e.g., —Si—O—Si—)). In one embodiment R2 is aryl, for example phenyl, naphthyl or the like. In another embodiment R2 is an aryl substituted hydrocarbon radical, for example benzyl, —CH₂CH₂C₆H₅, or the like. In another embodiment R2 is a branched C3-C6 alkoxy radical. In another embodiment R2 is a substituted or unsubstituted cyclic C5-C6 alkoxy radicals. Example R2 radicals include isopropoxy (—OCH(CH₃)CH₃, 2-propoxy), isobutoxy (1-methylpropoxy, —OCH(CH₃)CH₂CH₃), secbutoxy (2-methylpropoxy, —OCH₂CH(CH₃)CH₃)), tertbutoxy (2-methyl-2-propoxy, —OC(CH₃)₃)), and the like. In a preferred embodiment R2 is isopropoxy.

The alkenyl silane R3 and R4 radicals are independently selected from linear or branched C1-C6 alkoxy radicals, or substituted or unsubstituted cyclic C5-C6 alkoxy radicals. In one embodiment, R3 and R4 are identical.

In one embodiment the alkenyl silane is a trialkoxy silane in which the R2, R3, and R4 radicals are identical.

Example alkenyl silanes of the present invention include: vinyltriisopropoxysilane, allyltriisopropoxysilane, butenyltriisopropoxysilane, and vinylphenyldimethoxysilane. In a preferred embodiment, the alkenyl silane monomer of the present invention is vinyltriisopropoxysilane. In some embodiments, the alkenyl silane consists of, or consists essentially of vinyltriisopropoxysilane. Such alkenyl silanes are commercially available, for example from Gelest Inc., Morrisville, Pa., USA.

In one embodiment, the photocrosslinkable fluoropolymer consists essentially of, or alternately, consists of, repeating units arising from the monomers tetrafluoroethylene, methyl vinyl ether and vinyltriisopropoxysilane. In one embodiment, the photocrosslinkable fluoropolymer consists essentially of, or alternately, consists of repeating units arising from the monomers tetrafluoroethylene, ethyl vinyl ether and vinyltriisopropoxysilane.

In accordance with some embodiments, alkenyl silane is incorporated into the photocrosslinkable fluoropolymer in an amount of from 0.2 to 10 mole percent, based on the total amount of monomers used to form the fluoropolymer. In other embodiments, alkenyl silane is incorporated into the fluoropolymer in an amount of from 1.2 to 8 mole percent, and, in still other embodiments, in an amount of from 1.4 to 7 mole percent.

In one embodiment, the photocrosslinkable fluoropolymer comprises from 40 to 60 mole percent repeat units arising from fluoroolefin, from 40 to 60 mole percent repeat units arising from alkyl vinyl ether or aryl vinyl ether, and from 0.2 to 10 mole percent of repeat units arising from alkenyl silane. In one embodiment, the photocrosslinkable fluoropolymer consists essentially of from 40 to 60 mole percent repeat units arising from fluoroolefin, from 40 to 60 mole percent repeat units arising from alkyl vinyl ether or aryl vinyl ether, and from 0.2 to 10 mole percent of repeat units arising from alkenyl silane. In one embodiment, the photocrosslinkable fluoropolymer consists of from 40 to 60 mole percent repeat units arising from fluoroolefin, from 40 to 60 mole percent repeat units arising from alkyl vinyl ether or aryl vinyl ether, and from 0.2 to 10 mole percent of repeat units arising from alkenyl silane.

In one embodiment of the present composition for forming a photocrosslinked fluoropolymer coating, the photocrosslinkable fluoropolymer comprises repeat units arising from tetrafluoroethylene, ethyl vinyl ether, and vinyltriisopropoxysilane, the fluoropolymer has a weight average molecular weight of from 50,000 to 330,000 daltons, the carrier medium is propylene glycol monomethyl ether acetate, and the solution contains from 15 to 25 weight percent of the fluoropolymer. In another embodiment of the present composition for forming a photocrosslinked fluoropolymer coating, the photocrosslinkable fluoropolymer comprises repeat units arising from tetrafluoroethylene, ethyl vinyl ether, and vinyltriisopropoxysilane, the fluoropolymer has a weight average molecular weight of from 120,000 to 330,000 daltons, the carrier medium is propylene glycol monomethyl ether acetate, and the solution contains from 15 to 25 weight percent of the fluoropolymer. In another embodiment of the present composition for forming a photocrosslinked fluoropolymer coating, the photocrosslinkable fluoropolymer comprises from 40 to 60 mole percent repeat units arising from tetrafluoroethylene, from 40 to 60 mole percent repeat units arising from ethyl vinyl ether, and from 0.2 to 10 mole percent of repeat units arising from vinyltriisopropoxysilane, the fluoropolymer has a weight average molecular weight of from 50,000 to 330,000 daltons, the carrier medium is propylene glycol monomethyl ether acetate, and the solution contains from 15 to 25 weight percent of the fluoropolymer. In another embodiment of the present composition for forming a photocrosslinked fluoropolymer coating, the photocrosslinkable fluoropolymer comprises from 40 to 60 mole percent repeat units arising from tetrafluoroethylene, from 40 to 60 mole percent repeat units arising from ethyl vinyl ether, and from 0.2 to 10 mole percent of repeat units arising from vinyltriisopropoxysilane, the fluoropolymer has a weight average molecular weight of from 120,000 to 330,000 daltons, the carrier medium is propylene glycol monomethyl ether acetate, and the solution contains from 15 to 25 weight percent of the fluoropolymer.

In accordance with some embodiments, the photocrosslinkable fluoropolymer has a weight average molecular weight of from 10,000 to 350,000 daltons. In accordance with other embodiments, the photocrosslinkable fluoropolymer has a weight average molecular weight of from 100,000 to 350,000 daltons. In other embodiments, photocrosslinkable fluoropolymer weight average molecular weight can be in a range comprising a minimum weight average molecular weight to a maximum weight average molecular weight wherein the minimum is 10,000, or 20,000, or 30,000, or 40,000, or 50,000, or 60,000, or 70,000, or 80,000, or 90,000, or 100,000, or 110,000, or 120,000, or 125,000, or 130,000, or 140,000, or 150,000, or 160,000 or 170,000 and the maximum is 350,000, or 340,000, or 330,000, or 320,000, or 310,000 or 300,000 daltons. In one embodiment the photocrosslinkable fluoropolymer has a weight average molecular weight of 200,000 daltons.

The photocrosslinkable fluoropolymer can be produced according to known methods. In some embodiments, the monomers can be polymerized without the use of a solvent, and in other embodiments the monomers can be polymerized in a solvent, which may or may not be a solvent for the photocrosslinkable fluoropolymer. In other embodiments, the photocrosslinkable fluoropolymer can be produced by the emulsion polymerization of the monomers. To produce the desired photocrosslinkable fluoropolymer, the monomers, at least one free radical initiator and, optionally, an acid acceptor can be charged to an autoclave and heated to a temperature of from 25° C. to 200° C. for 10 minutes to 24 hours at a pressure of from atmospheric pressure to as high as 1,500 atmospheres. The resulting product can then be removed from the autoclave, filtered, rinsed and dried to give the photocrosslinkable fluoropolymer.

Suitable free radical initiators used in the polymerization methods to manufacture the photocrosslinkable fluoropolymer can be any of the known azo and/or peroxide initiators. For example, di(4-t-butylcyclohexyl)dicarbonate, di-t-butyl peroxide, acetyl peroxide, lauroyl peroxide, benzoyl peroxide, 2,2-azodiisobutyronitrile, 2,2-azobis(2,4-dimethyl-4-methoxyvaleronitrile), dimethyl-2,2-azobis(isobutyrate) or a combination thereof can be used. The amount of free radical initiators that can be used range of from 0.05 to 4 percent by weight, based on the total amount of the monomers in the monomer mixture. In other embodiments, the amount of free radical initiators used is from 0.1 to 3.5 percent by weight, and, in still further embodiments, is from 0.2 percent by weight to 3.25 percent by weight. All percentages by weight are based on the total amount of the monomers in the monomer mixture.

An acid acceptor can also be used in the polymerization methods to form the photocrosslinkable fluoropolymer. The acid acceptor can be a metal carbonate or metal oxide, for example, sodium carbonate, calcium carbonate, potassium carbonate, magnesium carbonate, barium oxide, calcium oxide, magnesium oxide or a combination thereof. The acid acceptor can be present from 0 to 5 percent by weight. In other embodiments, the acid acceptor can be present from 0.1 percent by weight to 4 percent by weight, and, in still further embodiments, can be present from 0.2 percent by weight to 3 percent by weight. All percentages by weight are based on the total amount of the monomers in the monomer mixture. The acid acceptor is present in order to neutralize acids, such as hydrogen fluoride that may be present in the fluoroolefin or may be generated during the course of the polymerization.

The present disclosure also relates to a coating composition for forming a photocrosslinked fluoropolymer coating comprising

i) photocrosslinkable fluoropolymer, ii) a photoacid generator, iii) an optional photosensitizer; and iv) a carrier medium. The coating composition can also optionally comprise v) an additive. The coating composition enables the manufacture of a continuous coating of the photocrosslinkable fluoropolymer on a substrate, after which the photocrosslinkable fluoropolymer is photocrosslinked. The coating composition can be prepared by simply mixing the components together at room temperature in the desired proportions. The major components of the coating composition are the photocrosslinkable fluoropolymer and the carrier medium. Generally, the coating composition comprises from 5 to 35 weight percent of photocrosslinkable fluoropolymer and from 65 to 95 weight percent of carrier medium. Above 35 weight percent photocrosslinkable fluoropolymer the viscosity of the coating composition becomes difficult to coat at room temperature. Below 5 weight percent of photocrosslinkable fluoropolymer the thickness of the films generated (in a one coat coating process) become too thin for utility as coating layer. In some embodiments the coating composition comprises from 10 to 30 weight percent of photocrosslinkable fluoropolymer and from 70 to 90 weight percent of carrier medium.

Suitable ii) photoacid generators are known in the art and can include, for example, (p-isopropylphenyl)(p-methylphenyl)iodonium tetrakis(pentafluorophenyl)-borate, IRGACURE® GSID-26-1 which is a salt of tris[4-(4-acetylphenyl)sulfanylphenyl] sulfonium and tris(trifluoromethanesulfonyl)methide and is available from BASF, Florham Park, N.J., bis(1,1-dimethylethylphenyl)iodonium salt with tris[(trifluoromethane)sulfonyl]methane also available from BASF, bis(4-decylphenyl)iodonium hexafluoroantimonate oxirane, mono[(C12-C14-alkoxy)methyl] derivatives, available from Momentive as UV9387C, 4,4′,4″-tris(t-butylphenyl)sulfonium triflate, 4,4′-di-t-butylphenyl iodonium triflate, diphenyliodonium tetrakis(pentafluorophenyl)sulfonium borate, triarylsulfonium-tetrakis(pentafluorophenyl) borate, triphenylsulfonium tetrakis(pentafluorophenyl) sulfonium borate, 4,4′-di-t-butylphenyl iodonium tetrakis(pentafluorophenyl) borate, tris(t-butylphenyl) sulfonium tetrakis(pentafluorophenyl) borate, 4-methylphenyl-4-(1-methylethyl)phenyl iodonium tetrakis(pentafluorophenyl) borate or a combination thereof. IRGACURE® GSID-26-1 photoacid generator is especially useful as it does not require the separate addition of a photosensitizer. The photoacid generator can be present in the coating composition in an amount from 0.01 to 5 percent by weight, based on the total amount of the coating composition minus carrier medium. In other embodiments, the photo acid generator can be present from 0.1 to 2 percent by weight, and, in still further embodiments, can be present in an amount from 0.3 to 1.0 percent by weight, based on the total amount of the coating composition minus carrier medium.

The coating composition for forming the present photocrosslinked fluoropolymer coating can also optionally comprise a iii) photosensitizer. Suitable photosensitizers can include, for example, chrysenes, benzpyrenes, fluoranthrenes, pyrenes, anthracenes, phenanthrenes, xanthones, indanthrenes, thioxanthen-9-ones or a combination thereof. In some embodiments, the photosensitizer can be 2-isopropyl-9H-thioxanthen-9-one, 4-isopropyl-9H-thioxanthen-9-one, 1-chloro-4-propoxythioxanthone, 2-isopropylthioxanthone, phenothiazine or a combination thereof. The optional photosensitizer can be used in an amount from 0 to 5 percent by weight, the percentage by weight based on the total amount of the coating composition minus carrier medium. In other embodiments, the photosensitizer can be present in the coating composition in an amount from 0.05 to 2 percent by weight, and, in still further embodiments, from 0.1 to 1 percent by weight. All percentages by weight reported for photoacid generator and photosensitizer in the present coating compositions are based on the total weight of solid components in the coating composition.

The coating composition for forming the photocrosslinked fluoropolymer coating is typically applied to at least a portion of a substrate as a solution or dispersion of the coating composition in iv) a carrier medium (solvent). This allows a layer of the coating composition to be applied and results in a smooth defect-free layer of coating composition on the substrate. Suitable carrier medium can include, for example, ketones, ethers, ether esters and halocarbons. In some embodiments, for example, the carrier medium can be a ketone, for example, acetone, acetylacetone, methyl ethyl ketone, methyl isobutyl ketone, methyl amyl ketone, 2-pentanone, 3-pentanone, 2-heptanone, 3-heptanone, cyclopentanone, cyclohexanone; ester, for example, ethyl acetate, propyl acetate, butyl acetate, isobutyl acetate, pentyl acetate, cyclohexyl acetate, heptyl acetate, ethyl propionate, propyl propionate, butyl propionate, isobutyl propionate, propylene glycol monomethyl ether acetate, propylene glycol monoethyl ether acetate, methyl lactate, ethyl lactate, gamma-butyrolactone; ether, for example, diisopropyl ether, dibutyl ether, ethyl propyl ether, anisole; or halocarbon, for example, dichloromethane, chloroform, tetrachloroethylene; or a combination thereof of the named carrier medium. In some embodiments, the carrier medium is methyl isobutyl ketone, 2-heptanone, propylene glycol methyl ether acetate or a combination thereof. In some embodiments, the solvent is an unreactive solvent, meaning that the carrier medium does not become a part of the photocrosslinked coating after the curing step.

The photocrosslinkable coating composition can also comprise v) one or more optional additives. Suitable additives can include, for example, viscosity modulators, fillers, dispersants, binding agents, surfactants, antifoaming agents, wetting agents, pH modifiers, biocides, bacteriostats or a combination thereof. Such additives are well known in the art. Typically, the additives comprise less than 10 percent by weight of the coating composition.

The present disclosure also relates to a process for forming a photocrosslinked coating comprising: (1) providing a photocrosslinkable coating composition comprising: i) a photocrosslinkable fluoropolymer having repeat units arising from monomers comprising: (a) fluoroolefin selected from the group consisting of tetrafluoroethylene, chlorotrifluoroethylene, hexafluoropropylene, perfluoro(methyl vinyl ether), perfluoro(ethyl vinyl ether), and perfluoro(propyl vinyl ether); (b) alkyl vinyl ether wherein the alkyl group is a C1 to C6 straight chain saturated hydrocarbon radical or a C3 to C6 branched chain or cyclic saturated hydrocarbon radical, or aryl vinyl ether wherein the aryl group is unsubstituted or substituted; and (c) alkenyl silane of the formula SiR1R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical; ii) a photoacid generator; iii) an optional photosensitizer; and iv) a carrier medium; (2) applying a layer of the photocrosslinkable coating composition onto at least a portion of a substrate; (3) removing at least a portion of the carrier medium; (4) irradiating at least a portion of the layer of the photocrosslinkable coating composition with ultraviolet light; (5) heating the applied layer of photocrosslinkable coating composition; and (6) removing at least a portion of the uncrosslinked photocrosslinkable fluoropolymer. In one embodiment: the photocrosslinkable fluoropolymer has a number average molecular weight of from 10,000 to 350,000 daltons; the layer of photocrosslinked coating composition has a dielectric constant of from 2.0 to 3.0 when measured at 1 MHz; and the layer of the photocrosslinked coating composition has a thickness of from 0.5 to 15 micrometers and has photocrosslinked features having a width of 0.5 micrometers or greater.

The thickness of the applied layer of photocrosslinked coating composition is from 0.5 to 15 micrometers. In some embodiments, the thickness of the applied layer of photocrosslinked coating composition is from 1 to 15 micrometers. In some embodiments, the thickness of the applied layer of photocrosslinked coating composition is from 4 to 10 micrometers.

The layer of the photocrosslinkable coating composition can be applied to a variety of substrates, including electrically conductive materials, semiconductive materials and/or nonconductive materials. For example, the substrate can be glass, polymeric, inorganic semiconductor, organic semiconductor, tin oxide, zinc oxide, titanium dioxide, silicon dioxide, indium oxide, indium zinc oxide, zinc tin oxide, indium gallium oxide, gallium nitride, gallium arsenide, indium gallium zinc oxide, indium tin zinc oxide, cadmium sulfide, cadmium selenide, silicon nitride, copper, aluminum, gold, titanium or a combination thereof. The layer of the photocrosslinkable coating composition can be applied by spin coating, spray coating, flow coating, curtain coating, roller coating, brushing, inkjet printing, screen printing, offset printing, gravure printing, flexographic printing, lithographic printing, dip coating, blade coating or drop coating methods. Spin coating involves applying an excess amount of the photocrosslinkable coating composition to the substrate, then rotating the substrate at high speeds to spread the composition by centrifugal force. The thickness of the resultant film can be dependent on the spin coating rate, the concentration of the photocrosslinkable coating composition, as well as the carrier medium used. Ambient conditions such as temperature, pressure, and humidity can also effect the thickness of the applied layer of photocrosslinkable coating composition.

After application to the substrate and prior to irradiation (photocrosslinking), at least a portion of the carrier medium can be removed by exposing the applied layer of coating composition to elevated temperatures, exposure to less than atmospheric pressure, by directly or indirectly blowing gas onto the applied layer, or by using a combination of these methods. For example, the applied layer of coating composition may be heated in air or in a vacuum oven optionally with a small purge of nitrogen gas. In other embodiments, the applied layer of coating composition can be heated to a temperature of from 60 to 110° C. in order to remove the carrier medium.

At least a portion of the applied layer of photocrosslinkable coating composition can then be irradiated (i.e., photocrosslinked) by exposure to light. The light is typically ultraviolet (UV) light at a wavelength of 150 to 500 nanometers (nm). In some embodiments, the ultraviolet light can be at a wavelength of from 200 to 450 nanometers, and, in other embodiments, from 325 to 425 nm. In still further embodiments, the exposure can be carried out by exposure to multiple wavelengths, or by irradiation at selected wavelengths, for example, 404.7 nanometers, 435.8 nanometers or 365.4 nanometers. Many suitable UV lamps are known in the industry and can be used.

The photocrosslinkable coating composition can be photocrosslinked using UV-A light. Crosslinking can be achieved when the total exposure to the light source is from 10 millijoules/centimeter² (millijoules/cm²) to 10,000 millijoules/cm². In other embodiments, the ultraviolet light exposure can be from 50 to 600 millijoules/cm². Exposure can be carried out in air or a nitrogen atmosphere.

In order to form the desired crosslinked features, at least a portion of the applied layer of photocrosslinkable coating composition can be irradiated to begin the crosslinking process only to those portions that were irradiated. The applied layer of photocrosslinkable coating composition can be masked or the step of irradiation can be performed using a focused light source so that the light contacts only those portions that are to be crosslinked. These techniques are well-known in the art. For example, a mask can be applied directly to the applied layer of photocrosslinkable coating composition. This method is known as contact printing. In another embodiment, called proximity printing, the mask is held slightly above the applied layer of photocrosslinkable coating composition without actually contacting the layer. In a third embodiment, an optical exposure device that precisely projects and focuses the light so that an actual physical mask is not needed. In some embodiments, the mask can be a chrome or other metal mask.

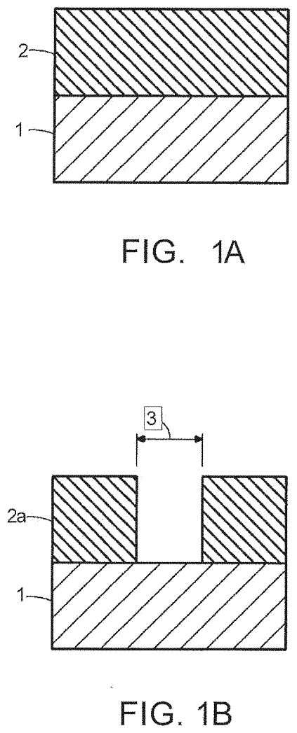

FIG. 1 shows cross sectional view of an example of the photocrosslinked feature. In FIG. 1A, a substrate 1 is shown with a layer of the photocrosslinkable coating composition 2 applied thereon. FIG. 1B depicts the substrate 1 and the photocrosslinked coating composition 2a after irradiating a portion of the photocrosslinkable coating composition and removing the uncrosslinked portion of the coating composition. The distance as measured by the width 3 is the width of the photocrosslinked feature.

After exposure to UV light, the layer of coating composition can be heated. The heating step can be done at a temperature of from 60 to 150° C. In other embodiments, the heating can be done at a temperature of from 60 to 130° C., and in still further embodiments, at a temperature of from 80° C. to 110° C. The coating composition can be exposed to the elevated temperature for 15 seconds to 10 minutes. In other embodiments, the time can be from 30 seconds to 5 minutes, and in still further embodiments, from 1 to 3 minutes.

Once the coating composition has been heated, uncrosslinked photocrosslinkable coating composition can be removed by dissolving in a carrier medium that dissolves the uncrosslinked photocrosslinkable fluoropolymer. Occasionally, a small amount of uncrosslinked photocrosslinkable coating composition can remain after the removal step. Remaining such fluoropolymer can be removed if necessary using plasma or a second wash step. The carrier medium can be a mixture of a solvent and a nonsolvent for the photocrosslinkable fluoropolymer. In some embodiments, the ratio of solvent to nonsolvent can be from 1:0 to 3:1. In other embodiments, the ratio of solvent to nonsolvent can be from 1:0.1 to 3:1. The solvents can be any of those that are listed as carrier medium that have the ability to solvate the uncrosslinked photocrosslinkable fluoropolymer. In some embodiments, the solvent can be methyl isobutyl ketone, 2-heptanone, propylene glycol monomethyl ether acetate or a combination thereof. In other embodiments, the nonsolvent can be hexane and/or isopropanol. In some embodiments, the application of the solvents to remove uncrosslinked photocrosslinkable coating composition can be carried out in a step-wise fashion. In one embodiment, a two step process can be used, wherein the first step involves treatment with solvent or mixture of a solvent and a nonsolvent, and the second step involves treatment with nonsolvent or a mixture of a solvent and a nonsolvent. In another embodiment, a multi-step process can be used, for example a three step process, wherein the first step involves treatment with solvent, the second step involves treatment with a mixture of a solvent and a nonsolvent, and the third step involves treatment with nonsolvent.

In some embodiments, after removal of uncrosslinked photocrosslinkable coating composition using solvent, the substrate containing the applied layer of photocrosslinked coating composition can be final thermally cured, sometimes referred to in this field as “hard baking”. This heating step can be carried out on the present photocrosslinked coating composition at a temperature of from 170° C. to 210° C., preferably 190° C., for a time period of from 0.5 to 3 hours. In other embodiments, this heating step can be carried out at even higher temperatures, and for relatively shorter periods of time, provided that these higher temperatures do not negatively effect the coated substrate. The final hard baking step provides a final photocrosslinked coating composition on the substrate, and the resultant electronic device can then be further processed as necessary.

The coating layer of the present disclosure can also be used as a bank layer in a light emitting diode. In this particular application, the coating layer can be used to separate one diode from another, for example, in the production of a display device using organic light emitting diodes, the bank layer can act as a barrier layer separating the red, blue and green light emitting diodes. It can be especially useful as a bank layer for organic light emitting diodes.

The present disclosure also relates to articles comprising a layer of the photocrosslinked coating composition.

### EXAMPLES

### Source of Chemicals:

a) PGMEA (1-Methoxy-2-propyl acetate, Lithography Grade, from JT Baker, JTB-6343-05, Center Valley, Pa.)
b) Vinyl triisopropoxy silane (Gelest Chemicals, SIV9210, Morrisville, Pa.)
c) 1,1,1,3,3-pentafluorobutane (Alfa Aesar, H33737, Ward Hill, Mass.)
d) Ethyl vinyl ether (Alfa Aesar, A15691-0F, Ward Hill, Mass.)
e) Potassium carbonate, anhydrous (EMD, PX1390-1, Philadelphia, Pa.)
f) V-601 initiator, dimethyl 2,2′-azobisisobutyrate (Wako Chemicals, Richmond, Va.)
g) Acetone (Fisher Scentific, A929-4, Fair Lawn, N.J.)
h) 2-Isopropylthioxanthone (TCI America, 10678, CAS 5495-84-1)
i) (p-isopropylphenyl)(p-methylphenyl) iononium tetrakis(pentafluorophenyl) borate (Gelest, OMBO037, CAS 178233-72-2)

### Example 1: Preparation of poly(tetrafluoroethene/ethyl vinyl ether/vinyl triisopropoxysilane) (Fluoropolymer #1)

A 400 ml autoclave chilled to about ˜20° C. is loaded with 0.5 g of powdered potassium carbonate, 0.24 g V-601 initiator (dimethyl 2,2′-azobisisobutyrate), and 3.2 g of vinyl triisopropoxysilane, 36 g (0.5 mole) of ethyl vinyl ether, and 200 mL (250 g) 1,1,1,3,3-pentafluorobutane. The autoclave is evacuated and further loaded with 50 g (0.5 mole) of TFE. The reaction mixture is shaken and heated to 66° C. Pressure in the autoclave peaks at ˜200 psig, dropping to ˜75 psig 8 hours later. Upon cooling, a viscous liquid (˜230 g) is obtained. It is transferred to a 1 L Nalgene jar and diluted with 270 g of PGMEA. The jar is sealed with tape, and rolled for 2 hours on a roll mill. The polymer solution is transferred to a 2 L round-bottom glass flask, and vacuum is applied down to 25 Milibar (19 Torr) to remove volatiles. The resulting solution is passed through 0.2 to 0.45 micron cartridge filter under 20 PSIG air pressure. The filtration is smooth and efficient. A polymer solution (˜400 g total, ˜15% solid) is collected in a 0.5 L clean room quality bottle.

Nuclear magnetic resonance spectroscopy (NMR) shows composition of polymer: 50.0 mole % TFE, 48.5 mole % ethyl vinyl ether, and 1.5 mole % vinyl triisopropoxysilane. SEC in hexafluoroisopropanol shows Mw 200,000.

### Example 2. Preparation of poly(tetrafluoroethene/ethyl vinyl ether/vinylphenyldiethoxysilane) (Fluoropolymer #2)

A 400 ml autoclave chilled to about ˜20° C. is loaded with 0.5 g of powdered potassium carbonate, 0.24 g V-601 initiator (dimethyl 2,2′-azobisisobutyrate), and 3.06 g of vinylphenyldiethoxysilane, 36 g (0.5 mole) of ethyl vinyl ether, and 200 mL (250 g) 1,1,1,3,3-pentafluorobutane. The autoclave is evacuated and further loaded with 50 g (0.5 mole) of TFE. The reaction mixture is shaken and heated to 66° C. Pressure in the autoclave peaks at ˜200 psig, dropping to ˜75 psig 8 hours later. Upon cooling a viscous liquid (˜230 g) is obtained. To the mixture is added acetone (75 mL), and it is shaken for a few minutes and a less viscous liquid results. The resulting mixture is passed through 0.2 to 0.45 micron cartridge filter under 20-30 PSIG air pressure. The filtration is smooth and efficient. The polymer solution is collected in an aluminum pan lined with PTFE film. It is dried in a vacuum oven (no heat) with high vacuum and dry ice trap for 5 hours, then with house vacuum with nitrogen flashing for 3 days. About 60 g polymer solid is obtained. NMR shows composition of polymer: 50.0 mole % TFE, 48.5 mole % ethyl vinyl ether, and 1.5 mole % vinylphenyldiethoxysilane. SEC in THF shows molecular weight: Mw ˜170,000.

### Example 3. Preparation of poly(tetrafluoroethene/ethyl vinyl ether/vinyltris(1-methoxy-2-propoxy)silane) (Fluoropolymer #3)

A 400 ml autoclave chilled to about ˜20° C. is loaded with 0.5 g of powdered potassium carbonate, 0.24 g V-601 initiator (dimethyl 2,2′-azobisisobutyrate), and 3.06 g of vinyltris(1-methoxy-2-propoxy)silane, 36 g (0.5 mole) of ethyl vinyl ether, and 200 mL (250 g) 1,1,1,3,3-pentafluorobutane. The autoclave is evacuated and further loaded with 50 g (0.5 mole) of TFE. The reaction mixture is shaken and heated to 66° C. Pressure in the autoclave peaks at ˜200 psig, dropping to ˜75 psig 8 hours later. Upon cooling a viscous liquid (˜230 g) is obtained. To the mixture is added acetone (75 mL), and it is shaken for a few minutes and a less viscous liquid results. The resulting mixture is passed through 0.2 to 0.45 micron cartridge filter under 20-30 PSIG air pressure. The filtration is smooth and efficient. The polymer solution is collected in an aluminum pan lined with PTFE film. It is dried in a vacuum oven (no heat) with high vacuum and dry ice trap for 5 hours, then with house vacuum with nitrogen flashing for 3 days. About 60 g polymer solid is obtained. NMR shows composition of polymer: 50.0 mole % TFE, 48.5 mole % ethyl vinyl ether, and 1.5 mole % vinyltris(1-methoxy-2-propoxy)silane. SEC in THF shows molecular weight: Mw ˜170,000.

### Example 4: Passivation Formulation Using Fluoropolymer 1

Fluoropolymer 1 (6.00 g) is dissolved in 30.0 g (29.1 mL) PGMEA (0.97 g/mL) in a clean amber bottle by rolling on a roller mill for about 16 hours (overnight) resulting in a 20 wt % solution. To this solution, 2-isopropylthioxathone (0.030 g) and p-isopropylphenyl)(p-methylphenyl) iononium tetrakis(pentafluorophenyl) borate (0.030 g) is added and is mixed by rolling on roller mill for about 30 min.

### Example 5: Patterned Wafer Using Passivation Formulation

A 2-inch silicon wafer is cleaned with pressurized water followed by acetone, and then isopropanol (IPA) and dried completely using pressurized N₂. The wafer is put on a spin coater and visually centered. Approximately 3 mL of passivation formula from example 4 is poured onto the wafer and spread at 500 rpm for 5 sec. The wafer is then spun for 30 sec at 2,000 rpm. Once the spinning is stopped, the coated wafer is removed from the spin coater and it is baked for 200 sec at 90° C. on a precision hot plate.

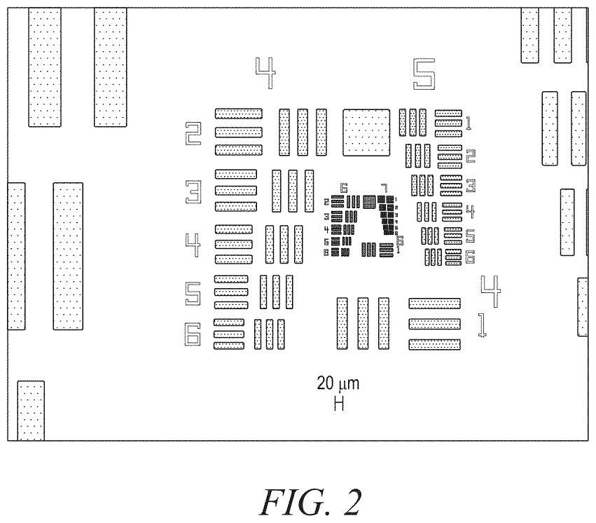

The baked wafer is exposed to 100˜120 mJ/cm² UV light on NXQ8000 mask aligner with a custom designed mask. After the exposure, post-exposure baking of the wafer is carried out at 90° C. for 120 seconds. Two solvent baths containing PGMEA and IPA are used for the developing step. The wafer is put into the PGMEA bath first, and the whole bath is gently shaken in circular motion for 4 min. Then the wafer is transferred to the IPA bath, and the whole bath is gently shaken in circular motion for 1 min. After these steps, the wafer is brought out of the IPA bath and dried using pressurized N₂ gun. The coated wafer is cured at 190° C. for 90 min on a precision hot plate. It is cooled to room temperature and images of the patterns are obtained via an optical microscope (Zeiss Axio). Thickness of the coating is ˜5 um measured using spectroscopic ellipsometer with 5-spot measurement method. FIG. 2 shows a plan view photomicrograph (with 20 micrometer scale bar) of the resultant wafer having the patterned passivation layer.

### Example 6: Pressed Sample from Fluoropolymer 1

Passivation formulation from example 4 is dried first with vacuum oven (no heat) with high vacuum and dry ice trap for 5 hours, then with house vacuum with nitrogen flashing for 3 days. Dried sample is carefully wrapped with PTFE film and then aluminum foil to prevent any UV light exposure. A hydraulic press (Pasadena Hydraulics Inc, model # P-21-8-C) is preheated to 100° C. A piece of stainless steel press plate is placed on the bottom press surface. A piece of 10 mil Teflon™ FEP film is placed on the press plate, and a piece of stainless steel metal with a 2.25 inch diameter circular cut off (1.0 mm thickness, as a mold for 2.25 inch diameter disc sample) was placed on top of the film. A dried polymer sample from above (˜4.50 g) is placed in the mold, followed by a piece of FEP film, then another press plate. The upper surface of the hot press is lowered to touch the assembly without significant pressure for ˜2 min to melt the polymer. Then 20,000 lb force is put on the assembly for ˜1 min followed by 38,000 lb for ˜5 min. After the pressure is released, the press is cooled down to ˜40° C. by water cooling system, and then the assembly is removed from the press. Molded 2.25 inch diameter 1.0 mm thickness sample is removed from the assembly after it is cooled to room temperature. The molded disc sample is passed through a Fusion UV Curing System with a 2,000 watt mercury lamp 5 times at the conveyer belt speed of 16 ft/min. Then the sample is baked for 2 hours at 200° C. in a N₂ atmosphere with water vapor feeding (introduced by nitrogen bubbling through water). A cured sample is obtained after cooling to room temperature.

### Example 7: Water Absorption Measurement for Pressed Sample from Fluoropolymer 1

Water absorption is measured with DVS-ET (Surface Measurement System Ltd) at 26° C. on a small sample (˜55 mg) cut from a sample from example 6. Weight change from 90% relative humidity to 10% relative humidity is 0.11%.

### Example 8: Dielectric Constant Measurement for Pressed Sample from Fluoropolymer 1

Dielectric constant and dissipation factor are measured using ASTM D150-11 method using 2.25 inch diameter disc samples from example 6 at 23° C. (±2° C.) and 50% (±10%) relative humidity. At 1 MHz, dielectric constant is 2.47, and the dissipation factor is 0.026.

### Example 9: Adhesion Comparison Between Polymer of tetrafluoroethylene, ethyl vinyl ether, and allyl glycidal ether (“Fluoropolymer #1” from WO2015/187413A1) and Example 1 Fluoropolymer 1

Test procedure: coated coupon (various substrates) is immersed in boiling water for 6 hours. It is taken out, dried, and visually inspected. Adhesion is checked using ASTM D3359-09 method (tape pull). Results are shown in Table 1:

TABLE 1

| | | | 6 Hours | |
|---|---|---|---|---|
| | | | Boiling | |
| | | | Water | |
| | | Additional | Visual | Tape |
| Polymer | Substrate | Treatment | Inspection | Pull |
| Polymer of | Glass | None | Fail | |
| tetrafluoroethylene, | Copper | None | Fail | |
| ethyl vinyl ether, | Steel | None | Fail | |
| and allyl glycidal | SiNx | Bake 2 hr/200° C. | Pass | Pass |
| ether (“fluoropolymer | Gold | Bake 2 hr/200° C. | Pass | Pass |
| #1” from WO2015/ | | | | |
| 187413A1) | | | | |
| Example 1 | Glass | None | Pass | Pass |
| fluoropolymer #1 | Copper | None | Pass | Pass |
| | Steel | None | Pass | Pass |
| | Aluminum | None | Pass | Pass |
| | Kapton ® | None | Pass | Pass |
| | SiNx | Bake 2 hr/200° C. | Pass | Pass |
| | Gold | Bake 2 hr/200° C. | Pass | Pass |

### Example 10: Patterned Wafer Using Passivation Formulation

A 2-inch silicon wafer is cleaned with pressurized water followed by acetone, and then isopropanol (IPA) and dried completely using pressurized N₂. The wafer is put on a spin coater and visually centered. Approximately 3 mL of passivation formula from example 4 is poured onto the wafer and spread at 500 rpm for 5 sec. The wafer is then spun for 30 sec at 2,000 rpm. Once the spinning is stopped, the coated wafer is removed from the spin coater and it is baked for 200 sec at 90° C. on a precision hot plate.

The baked wafer is exposed to 80 mJ/cm² UV light on KARLSUSS mask aligner with a custom designed mask. After the exposure, post-exposure baking of the wafer is carried out at 90° C. for 120 seconds. The wafer pattern is then developed using PGMEA and IPA. The wafer is put on a spinner and spun at 1,500 rpm for 5 seconds after rinsing with PGMEA. The wafer is then covered with PGMEA for 55 seconds, the PGMEA is then removed, and then the wafer is spun at 1,500 rpm for 5 seconds. The previous step is repeated four times. The wafer is then rinsed with IPA, the IPA then removed, and the wafer is then spun at 2,000 rpm for 10 sec. After these steps, the wafer is dried using with N₂. The coated wafer is cured at 190° C. for 90 min on a precision hot plate. The wafer is then cooled to room temperature and images of the patterns are obtained via an optical microscope (Zeiss Axio/Leica). Thickness of the coating is ˜5 um measured using spectroscopic ellipsometer with 5-spot measurement method.

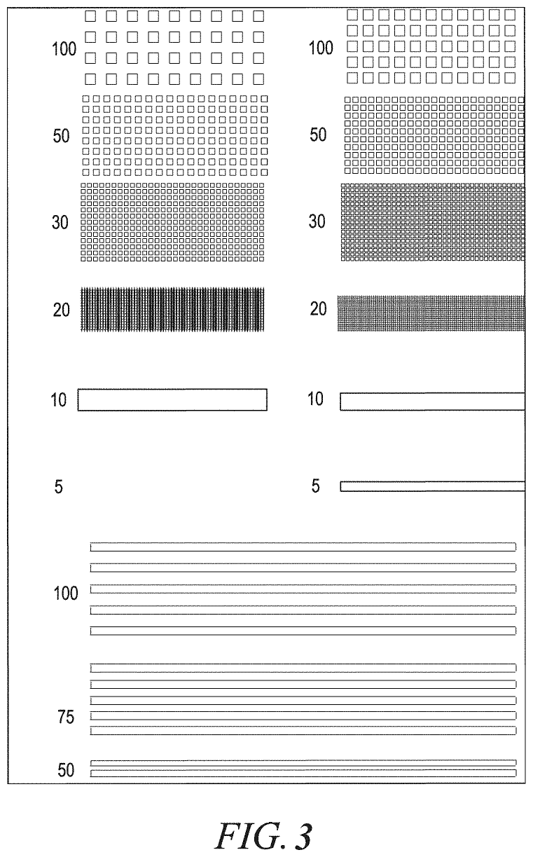

FIG. 3 is a plan view photomicrograph of the resultant wafer having the patterned passivation layer. The dark regions correspond to the presence of photocrosslinked fluoropolymer 1 layer, and the light regions correspond to the absence of fluoropolymer 1 layer—features where the fluoropolymer 1 has been removed/etched. The square features (square light regions) in the twelve sets of features in the top two-thirds of FIG. 3 correspond to 5, 10, 20, 30, 50 and 100 micrometer features. On the upper left hand side of this portion of FIG. 3, this corresponds to six sets of square features, each individual square being a 5, 10, 20, 30, 50 or 100 micrometer per side square, separated from one another by fluoropolymer 1 spacer of like width. On the upper right hand side of this portion of FIG. 3, this corresponds to six sets of square features, each individual square being a 5, 10, 20, 30, 50 or 100 micrometer per side square, separated from one another by fluoropolymer 1 spacer having thickness that is half the respective square side length. The horizontal line features in the bottom third of FIG. 3 corresponding to lines etched in the fluoropolymer 1 layer that are 50, 75 or 100 micrometers wide.

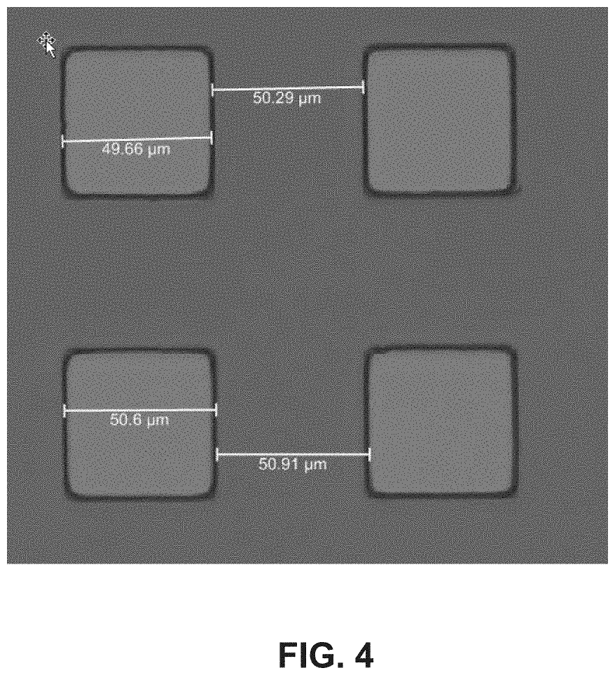

FIG. 4 is an expanded plan view photomicrograph with added measurement bars of features found in the upper left hand side “50” (micrometer) portion of FIG. 3. FIG. 4 shows four of the 50 micrometer square features separate by 50 micrometer regions of photocrosslinked fluoropolymer 1 layer.

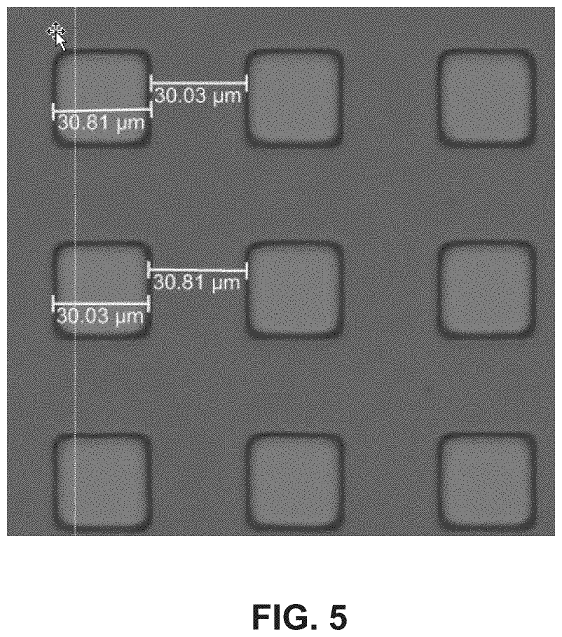

FIG. 5 is an expanded plan view photomicrograph with added measurement bars of features found in the upper left hand side “30” (micrometer) portion of FIG. 3. FIG. 5 shows nine of the 30 micrometer square features separate by 30 micrometer regions of photocrosslinked fluoropolymer 1 layer.

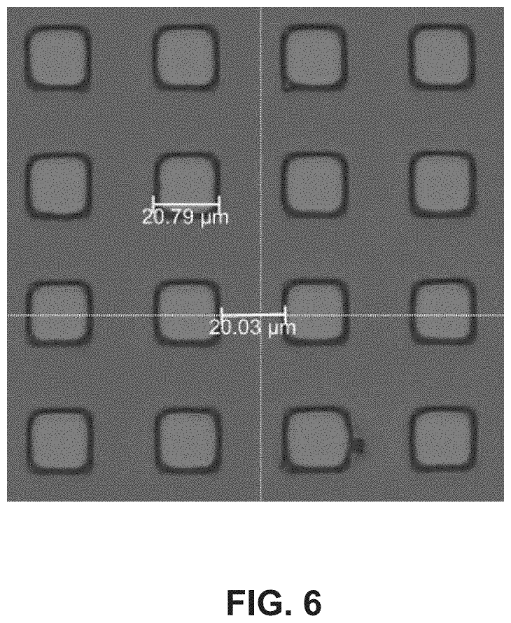

FIG. 6 is an expanded plan view photomicrograph with added measurement bars of features found in the upper left hand side “20” (micrometer) portion of FIG. 3. FIG. 6 shows sixteen of the 20 micrometer square features separate by 20 micrometer regions of photocrosslinked fluoropolymer 1 layer.

What is claimed is:

1. A coating layer comprising a layer of photocrosslinked coating composition disposed on at least a portion of a substrate, wherein said coating composition comprises:
i) a photocrosslinkable fluoropolymer having repeat units arising from monomers comprising:
(a) fluoroolefin selected from the group consisting of tetrafluoroethylene, chlorotrifluoroethylene, hexafluoropropylene, perfluoro(methyl vinyl ether), perfluoro(ethyl vinyl ether), and perfluoro(propyl vinyl ether);
(b) alkyl vinyl ether wherein the alkyl group is a C1 to C6 straight chain saturated hydrocarbon radical or a C3 to C6 branched chain or cyclic saturated hydrocarbon radical, or aryl vinyl ether wherein the aryl group is unsubstituted or substituted; and
(c) alkenyl silane of the formula SiR1R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical;
ii) a photoacid generator; and
iii) an optional photosensitizer;
wherein said photocrosslinkable fluoropolymer has a number average molecular weight of from about 10,000 to about 350,000 daltons, and wherein said photocrosslinked coating composition has a dielectric constant of from about 2.0 to about 3.0 when measured at 1 MHz, and wherein said layer of photocrosslinked coating composition has a thickness of from about 0.5 to about 15 micrometers and has photocrosslinked features having a width of about 0.5 micrometers or greater.

2. The coating layer of claim 1, wherein said alkyl vinyl ether is at least one selected from the group consisting of methyl vinyl ether, ethyl vinyl ether, n-propyl vinyl ether, isopropyl vinyl ether, n-butyl vinyl ether, sec-butyl vinyl ether, t-butyl vinyl ether, n-pentyl vinyl ether, isoamyl vinyl ether, hexyl vinyl ether, cyclohexyl vinyl ether or a combination thereof.

3. The coating layer of claim 1, wherein said photocrosslinked coating composition has water absorption values ranging from about 0.01 to about 0.8 percent by weight as measured by dynamic vapor sorption at standard temperature from 90% to 10% relative humidity.

4. The coating layer of claim 1, wherein said layer of the photocrosslinked coating has a thickness of about 4 micrometers to about 10 micrometers.

5. A process for forming a photocrosslinked coating, comprising:
(1) providing a photocrosslinkable coating composition comprising:
i) a photocrosslinkable fluoropolymer having repeat units arising from monomers comprising:
(a) fluoroolefin selected from the group consisting of tetrafluoroethylene, chlorotrifluoroethylene, hexafluoropropylene, perfluoro(methyl vinyl ether), perfluoro(ethyl vinyl ether), and perfluoro(propyl vinyl ether);
(b) alkyl vinyl ether wherein the alkyl group is a C1 to C6 straight chain saturated hydrocarbon radical or a C3 to C6 branched chain or cyclic saturated hydrocarbon radical, or aryl vinyl ether wherein the aryl group is unsubstituted or substituted; and
(c) alkenyl silane of the formula SiR1R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical;
ii) a photoacid generator;
iii) an optional photosensitizer; and
iv) a carrier medium;
(2) applying a layer of the photocrosslinkable coating composition onto at least a portion of a substrate;
(3) removing at least a portion of the carrier medium;
(4) irradiating at least a portion of the layer of the photocrosslinkable coating composition with ultraviolet light;
(5) heating the applied layer of photocrosslinkable coating composition; and
(6) removing at least a portion of the uncrosslinked photocrosslinkable fluoropolymer; wherein the photocrosslinkable fluoropolymer has a number average molecular weight of from about 10,000 to about 350,000 daltons, and wherein the layer of photocrosslinked coating composition has a dielectric constant of from about 2.0 to about 3.0 when measured at 1 MHz, and wherein the layer of the photocrosslinked coating composition has a thickness of from about 0.5 to about 15 micrometers and has photocrosslinked features having a width of about 0.5 micrometers or greater.

6. The process of claim 5, wherein the photocrosslinkable coating composition comprises about 5 to about 35 percent by weight of the photocrosslinkable fluoropolymer; from about 65 to about 95 weight percent of carrier medium based on the total weight of all components in the coating composition, and from 0 to about 5 percent by weight of the photosensitizer and from about 0.01 to about 5 percent by weight of the photoacid generator, wherein the percentages by weight of photosensitizer and photoacid generator are based on the total weight of all components in the coating composition minus the carrier medium.

7. The process of claim 5, wherein at least a portion of the carrier medium is removed by exposing the applied layer of photocrosslinkable coating composition to elevated temperatures, exposure to less than atmospheric pressure, by directly or indirectly blowing gas onto the substrate, or a combination thereof.

8. The process of claim 5 wherein the step (4) of irradiating is performed in air or a nitrogen atmosphere.

9. The process of claim 5, wherein the wavelength of ultraviolet light is from about 325 to about 425 nm.

10. The process of claim 5, wherein the ultraviolet light exposure is from about 10 to about 10,000 millijoules/cm².

11. The process of claim 5, wherein the heating step (5) occurs at a temperature of from about 60° C. to about 150° C. for about 15 seconds to about 10 minutes.

12. The process of claim 5, wherein the removing step (6) occurs by dissolving the photocrosslinkable fluoropolymer using a carrier medium that dissolves the photocrosslinkable fluoropolymer.

13. An article comprising the coating layer of claim 1.

14. A composition for forming a photocrosslinked fluoropolymer coating comprising:
i) a photocrosslinkable fluoropolymer having repeat units arising from monomers comprising:
(a) fluoroolefin selected from the group consisting of tetrafluoroethylene, chlorotrifluoroethylene, hexafluoropropylene, perfluoro(methyl vinyl ether), perfluoro(ethyl vinyl ether), and perfluoro(propyl vinyl ether);
(b) alkyl vinyl ether wherein the alkyl group is a C1 to C6 straight chain saturated hydrocarbon radical or a C3 to C6 branched chain or cyclic saturated hydrocarbon radical, or aryl vinyl ether wherein the aryl group is unsubstituted or substituted; and
(c) alkenyl silane of the formula SiR1R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical;
ii) a photoacid generator;
iii) an optional photosensitizer; and
iv) a carrier medium.

15. The composition of claim 14, wherein the alkyl vinyl ether is at least one selected from the group consisting of methyl vinyl ether, ethyl vinyl ether, n-propyl vinyl ether, isopropyl vinyl ether, n-butyl vinyl ether, sec-butyl vinyl ether, t-butyl vinyl ether, n-pentyl vinyl ether, isoamyl vinyl ether, hexyl vinyl ether, cyclohexyl vinyl ether or a combination thereof.

16. The composition of claim 14, wherein the carrier medium is methyl isobutyl ketone, 2-heptanone, propylene glycol methyl ether acetate or a combination thereof.

17. The composition of claim 14, wherein the composition comprises from about 5 to about 35 percent by weight of the photocrosslinkable fluoropolymer; from about 65 to about 95 weight percent of carrier medium based on the total weight of all components in the coating composition, and from 0 to about 5 percent by weight of the photosensitizer and from about 0.01 to about 5 percent by weight of the photoacid generator, wherein the percentages by weight of photosensitizer and photoacid generator are based on the total weight of all components in the coating composition minus the carrier medium.
